(19) United States
(12) Patent Application Publication
(10) Pub. No.: US 2012/0115306 A1
(43) Pub. Date: May 10, 2012

(54) DEFLECTOR ARRAY, CHARGED PARTICLE BEAM DRAWING APPARATUS, DEVICE MANUFACTURING METHOD, AND DEFLECTOR ARRAY MANUFACTURING METHOD

(75) Inventors: Toru Yamazaki, Utsunomiya-shi (JP); Masamichi Kuwabara, Utsunomiya-shi (JP); Yoshihiro Hirata, Utsunomiya-shi (JP)

(73) Assignee: CANON KABUSHIKI KAISHA, Tokyo (JP)

(21) Appl. No.: 13/289,350

(22) Filed: Nov. 4, 2011

(30) Foreign Application Priority Data
Nov. 9, 2010 (JP) 2010-251162

(51) Int. Cl. H01L 21/02; G21K 5/10; H01J 37/305; H01J 3/14

(52) U.S. Cl. 438/460; 250/396 R; 250/492.22; 264/485; 257/E21.214

(57) ABSTRACT

A deflector array includes a first base substrate including a plurality of apertures formed thereon, and a plurality of deflector chips including a plurality of apertures formed thereon and a plurality of electrode pairs disposed at both sides of at least a part of the plurality of apertures. The plurality of deflector chips is fixed to the first base substrate in such a manner that the plurality of apertures of the deflector chips is arranged at positions corresponding to the plurality of apertures of the first base substrate.

### BACKGROUND OF THE INVENTION

1. Field of the Invention

Embodiments of the present invention relate to a deflector array, particularly, a deflector array used with a charged particle beam drawing apparatus for drawing a pattern on a substrate with use of a plurality of charged particle beams.

2. Description of the Related Art

Multi charged particle beam drawing apparatuses, which use a plurality of charged particle beams, are employed in lithography in the semiconductor process. Japanese Patent Application Laid-Open No. 2002-353113 discusses such a charged particle beam drawing apparatus. This charged particle beam drawing apparatus includes a blanker array (blanking deflector array), which includes a plurality of electrode pairs formed on a single substrate for individually deflecting a plurality of charged particle beams.

As another related technique, Japanese Patent Application Laid-Open No. 2008-235571 discusses a blanking deflector array including electrode pairs, and a switching element disposed on the same substrate where the electrode pairs are disposed so as to apply voltage to the electrode pairs.

One possible measure to improve the throughput of a multi charged particle beam drawing apparatus is to increase the number of charged particle beams used therein.

However, in blanking deflector arrays of conventional charged particle beam drawing apparatuses, electrode pairs of the number corresponding to the total number of charged particle beams are formed on a single substrate. Therefore, increasing the number of charged particle beams results in a lower yield rate in manufacturing of blanking deflector arrays. Particularly, in a multi charged particle beam drawing apparatus, if a defect exists at a part of the plurality of electrode pairs constituting the blanking deflector array, it is highly likely that pattern drawing is adversely affected thereby, and therefore it is desirable to manufacture a blanking deflector array while reducing defects as much as possible.

### SUMMARY OF THE INVENTION

One disclosed aspect of the embodiments is directed to a highly reliable deflector array.

According to an aspect of the embodiments, a deflector array includes a first base substrate including a plurality of apertures formed thereon, and a plurality of deflector chips including a plurality of apertures formed thereon and a plurality of electrode pairs disposed at both sides of at least a part of the plurality of apertures. The plurality of deflector chips is fixed to the first base substrate in such a manner that the plurality of apertures of the deflector chips is arranged at positions corresponding to the plurality of apertures of the first base substrate.

Further features and aspects of the embodiments will become apparent from the following detailed description of exemplary embodiments with reference to the attached drawings.

### BRIEF DESCRIPTION OF THE DRAWINGS

The accompanying drawings, which are incorporated in and constitute a part of the specification, illustrate exemplary embodiments, features, and aspects of the invention and, together with the description, serve to explain the principles of the invention.

FIG. 1 illustrates a configuration of a multi charged particle beam drawing apparatus according to a first exemplary embodiment of the present invention.

FIG. 2 illustrates a structure of a deflector chip according to the first exemplary embodiment.

FIG. 3 illustrates a structure of a base substrate according to the first exemplary embodiment.

FIGS. 4A and 4B illustrate a configuration of a blanking deflector array according to the first exemplary embodiment.

FIG. 5 is a flowchart illustrating a process for manufacturing the blanking deflector array according to the first exemplary embodiment.

FIG. 6 illustrates a structure of a base substrate according to a second exemplary embodiment of the present invention.

FIGS. 7A and 7B illustrate a configuration of a blanking deflector array according to the second exemplary embodiment.

FIG. 8 illustrates a configuration of a blanking deflector array according to a third exemplary embodiment of the present invention.

FIG. 9 illustrates a configuration of a multi charged particle beam drawing apparatus according to a fourth exemplary embodiment of the present invention.

FIGS. 10A and 10B illustrate structures of deflector chips according to the fourth exemplary embodiment.

FIGS. 11A and 11B illustrate structures of base substrates according to the fourth exemplary embodiment.

FIGS. 12A and 12B illustrate configurations of blanking deflector arrays according to the fourth exemplary embodiment.

### DESCRIPTION OF THE EMBODIMENTS

Various exemplary embodiments, features, and aspects of the invention will be described in detail below with reference to the drawings. One disclosed feature of the embodiments may be described as a process which is usually depicted as a flowchart, a flow diagram, a timing diagram, a structure diagram, or a block diagram. Although a flowchart or a timing diagram may describe the operations or events as a sequential process, the operations may be performed, or the events may occur, in parallel or concurrently. In addition, the order of the operations or events may be re-arranged. A process is terminated when its operations are completed. A process may correspond to a method, a program, a procedure, a method of manufacturing or fabrication, a sequence of operations performed by an apparatus, a machine, or a logic circuit, etc. It is noted that the words “first”, “second”, etc. may be used to indicate differences and not necessarily to connote a sense of order or sequence.

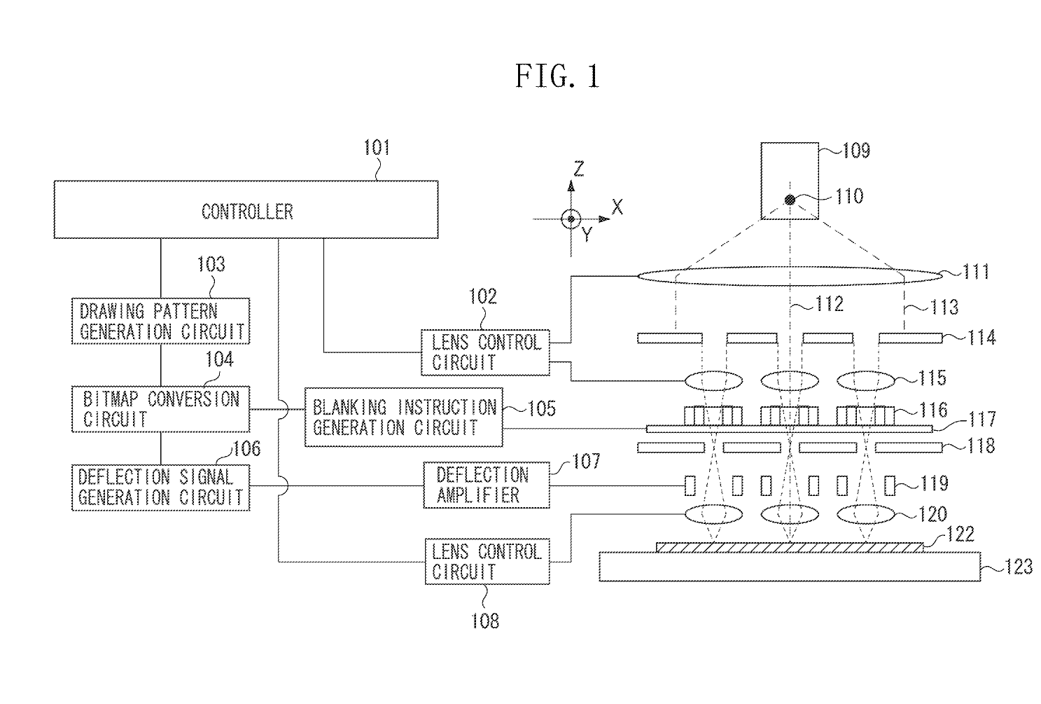

FIG. 1 illustrates a configuration of a multi charged particle beam drawing apparatus according to a first exemplary embodiment of the present invention. An electron gun (charged particle beam source) 109 forms a crossover 110. Lines 112 and 113 indicate the path of a charged particle beam spread from the crossover 110.

The charged particle beam spread from the crossover 110 is collimated by a collimator lens 111, which is constituted by an electromagnetic lens, to become a collimated beam, and is incident on an aperture array 114.

The aperture array 114 includes a plurality of circular apertures arranged in a matrix pattern, and the collimated beam incident on the aperture array 114 is divided into a plurality of charged particle beams.

The plurality of charged particle beams transmitted through the aperture array 114 is incident on an electrostatic lens 115 constituted by electrode plates including a plurality of circular apertures (in FIG. 1, vertically aligned three electrode plates are illustrated as an integrated structure).

A blanking aperture (blanking unit) 118 having a plurality of apertures arranged in a matrix pattern is disposed at a position where the electrostatic lens 115 forms a crossover. The electrostatic lens 115 and the collimator lens 111 are controlled based on a signal from a lens control circuit 102.

Blanking is performed with use of the blanking aperture 118 and a blanking deflector array 117 including a deflector chip 116 including electrode pairs arranged thereon in a matrix pattern.

The blanking deflector array 117 is controlled based on a blanking signal generated by a drawing pattern generation circuit 103, a bitmap conversion circuit 104, and a blanking instruction generation circuit 105.

The charged particle beams transmitted through the blanking aperture 118 are focused by an electrostatic lens 120, and form the image of the crossover 110 on a substrate 122 such as a wafer or a mask.

During pattern drawing, the substrate 122 is continuously shifted in the Y direction by a stage 123. The image formed on the surface of the substrate 122 is deflected in the X direction by a deflector 119, and is blanked by the blanking deflector array 117, based on a result of real-time length measurement by a laser length measurement unit. The deflector 119 is controlled based on a signal from a deflection signal generation circuit 106 via a deflection amplifier 107. The electrostatic lens 120 is controlled based on a signal from a lens control circuit 108. A controller 101 provides overall control of these control circuits. However, the control system is not limited to the above-described system.

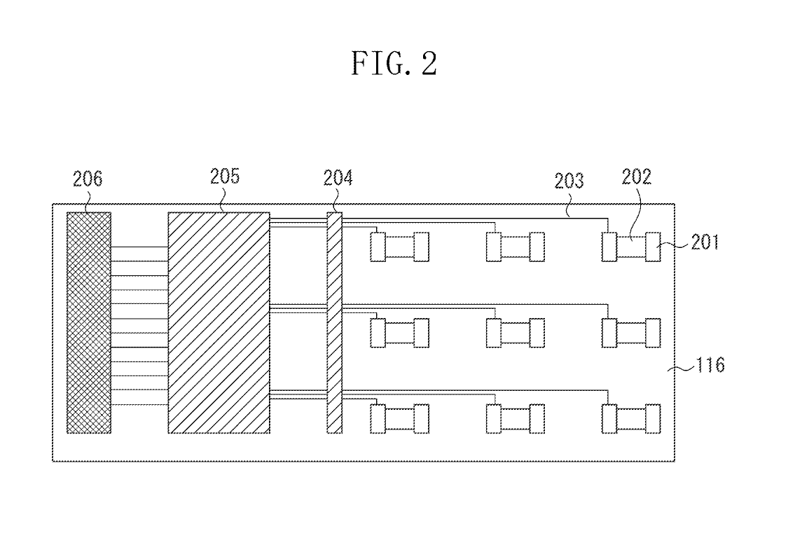

FIGS. 2 to 4A and 4B illustrate a configuration of the blanking deflector array 117.

FIG. 2 illustrates the deflector chip 116 capable of deflecting 3×3 charged particle beams.

The deflector chip 116 includes a plurality of apertures 202 through which charged particle beams may be transmitted, a plurality of electrode pairs (electrode portion) 201 disposed on the both sides of the apertures, and a driver 204 (switching element) configured to output voltage for driving the electrode pairs 201.

Further, the deflector chip 116 includes a control circuit 205 configured to control the driver 204, and a wiring pattern 203 (wiring portion) electrically connecting the electrode pairs 201 and the control circuit 205. Further, the deflector chip 16 includes a terminal 206 constituted by, for example, a bump or a pad mainly made of a solder, Cu, or Au material for inputting an ON/OFF signal of each charged particle beam from the blanking instruction generation circuit 105. The wiring pattern 203 is formed so as to apply voltage to the plurality of electrode pairs 201. Mounting the driver 204 on the deflector chip 116 is advantageous in terms of responsiveness, thereby allowing even a high-speed ON/OFF signal to be processed.

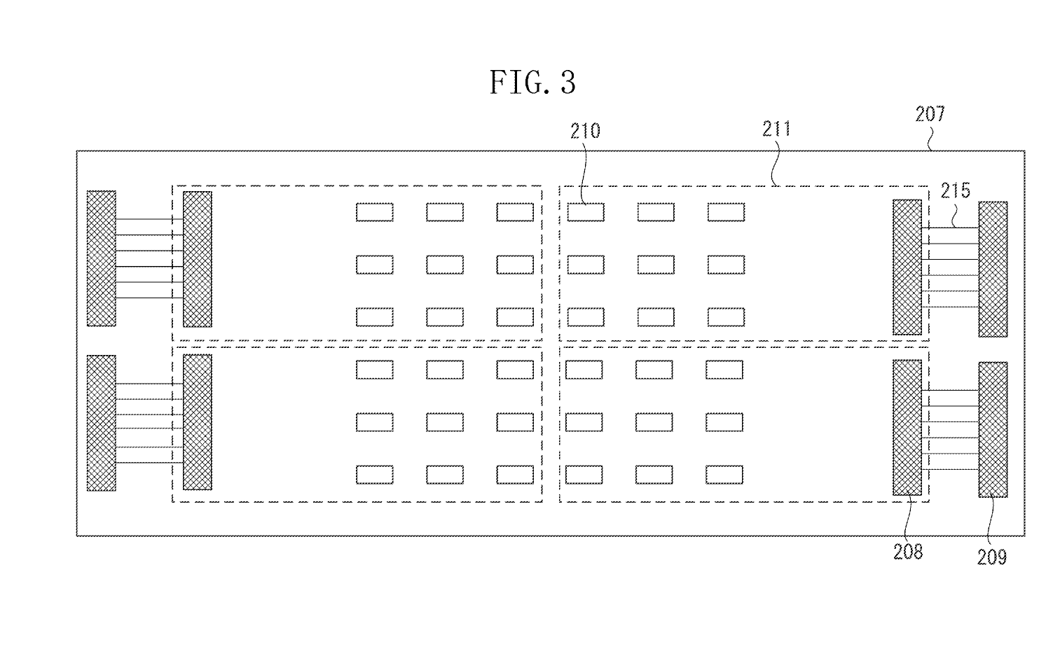

FIG. 3 illustrates a base substrate 207 to which the deflector chip 116 is fixed.

The base substrate 207 includes a plurality of apertures 210 formed thereon, and terminals 208 and 209 each constituted by, for example, a bump or a pad mainly made of a solder, Cu, or Au material for relaying an ON/OFF signal of each charged particle beam from the blanking instruction generation circuit 105 to the deflector chip 116. The plurality of apertures is formed so as to be located at positions corresponding to the plurality of charged particle beams (i.e., positions corresponding to the apertures of the aperture array), and to be arranged in the directions along the top surface of the base substrate 207 (for example, the X and Y directions).

Further, the base substrate 207 includes a wiring pattern 215 connecting the terminals 208 and 209. A broken line 211 schematically illustrates where the blanking chip 116 is fixed on the base substrate 207. A plurality of deflector chips 116 is fixed to one base substrate 207 in parallel with one another in such a manner that the plurality of apertures of the deflector chips 116 is located at positions corresponding to the plurality of apertures of the base substrate 207.

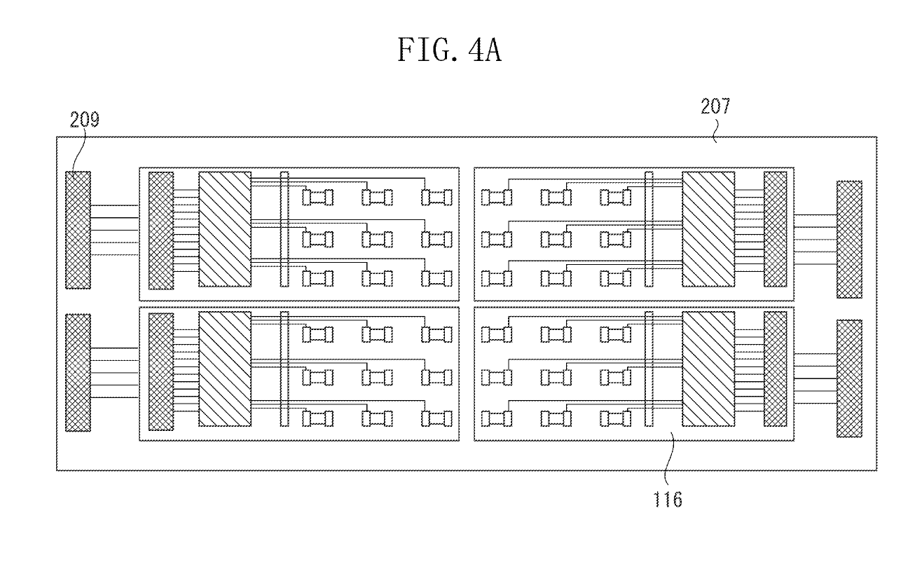

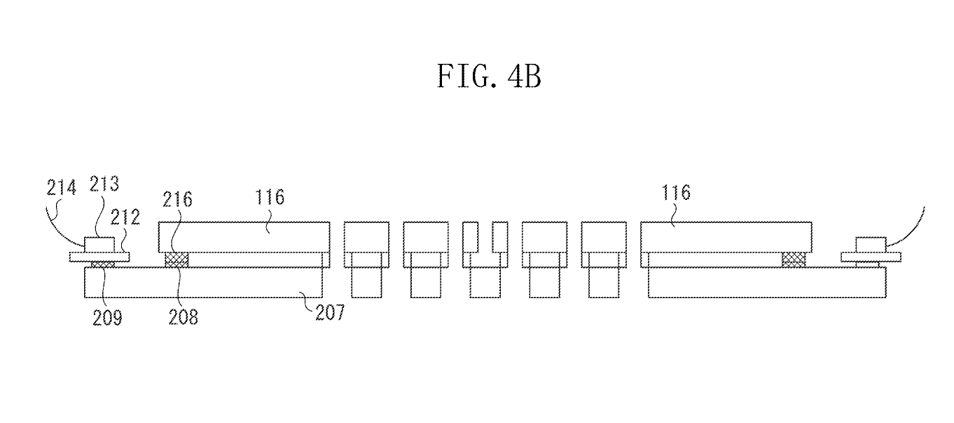

FIG. 4A illustrates how the deflector chip 116 illustrated in FIG. 2 is fixed to the base substrate 207 illustrated in FIG. 3. Mounting four deflector chips 116 enables blanking control of 6×6 charged particle beams. The area of the top surface (or the bottom surface) of the deflector chip 116 is sized so as to be smaller than the area of the top surface (or the bottom surface) of the base substrate 207. In the present exemplary embodiment, 6×6 is the total number of the plurality of charged particle beams in the charged particle beam drawing apparatus.

In the present exemplary embodiment, as one nonlimiting example, the plurality of deflection chips 116 have identical shapes. As a result, it is possible to improve the yield rate in manufacturing of the deflection chips 116, compared to a blanking deflector array using the deflector chips 116 having a plurality of kinds of shapes. Further, in the present exemplary embodiment, the plurality of deflector chips 116 is arranged so as to have different mounting angles. More specifically, referring to FIG. 4A, the deflector chip 116 on the left side and the deflector chip 116 on the right side are attached at mounting angles 180° different from each other. It is possible to easily ensure the space for layout of the wiring pattern 203 or wiring 214, which will be described below, by attaching the plurality of deflector chips 116 in such a manner that the terminals 206 of the deflector chips 116 each are positioned on the outer side of the base substrate 207. The terminals 206 of the deflector chips 116 each may be positioned at the opposite side to the adjacent deflector chip 116.

FIG. 4B is a cross-sectional view illustrating how the blanking deflector array 117 is connected to the blanking instruction generation circuit 105.

A control signal from the blanking instruction generation circuit 105 is transmitted to a communication processing substrate 212 with a communication processing circuit 213 formed thereon via the wiring 214 configured for serial transmission and constituted by an optical fiber or an electric cable.

The present exemplary embodiment employs the serial transmission method, but may employ the parallel transmission method via an optical fiber or an electric cable.

The communication processing substrate 212 and the terminal 209 of the base substrate 207 are connected to each other via a connection unit. In the present exemplary embodiment, this connection is established by the flip chip bonding method, but the connection may be established by a connector connection structure via wiring, or the wire bounding method.

The terminal 208 of the base substrate 207 and the terminal 206 of the deflector chip 116 are electrically connected to each other via a connection unit 216. In the present exemplary embodiment, this connection is established by the flip chip bonding method, but the connection may be established by a connector connection structure via wiring, or the wire bounding method. Further, this electric connection unit may be utilized for fixing the deflector chip 116 to the base substrate 207, or the deflector chip 116 may be fixed to the base substrate 207 by another additional fixing method such as bonding or fastening.

In this way, preparing a deflector chip for a blanking deflector array as the divided deflector chips 116 enables a size reduction of the deflector chip, thereby improving the yield rate, compared to preparing the blanking deflector array as an integrated one structure. Further, fixing the plurality of deflector chips 116 to the base substrate 207 enables easy positioning of the plurality of deflector chips 116, and thereby enables easy maintenance of the positional relationship among the plurality of deflector chips 116.

In the present exemplary embodiment, as one nonlimiting example, the charged particle beam drawing apparatus includes only one base substrate 207, to which the plurality of deflector chips 116 is fixedly attached. However, the charged particle beam drawing apparatus may include a plurality of base substrates arranged in parallel on the XY plane, and the plurality of deflector chips may be fixed to at least one of those base substrates.

The present exemplary embodiment employs the blanking deflector array 117 on which the four deflector chips 116 each having 3×3 apertures (electrode pairs) are mounted. However, the present exemplary embodiment may employ the deflector array 117 or the deflector chip 116 having any different numbers of columns and rows of the apertures (electrode pairs), and may use any different number of deflector chips 116.

Further, the present exemplary embodiment employs the deflection electrode array in which the plurality of apertures (electrode pairs) are arranged in a square matrix pattern, but may employ a deflection electrode array arranged in a staggered pattern.

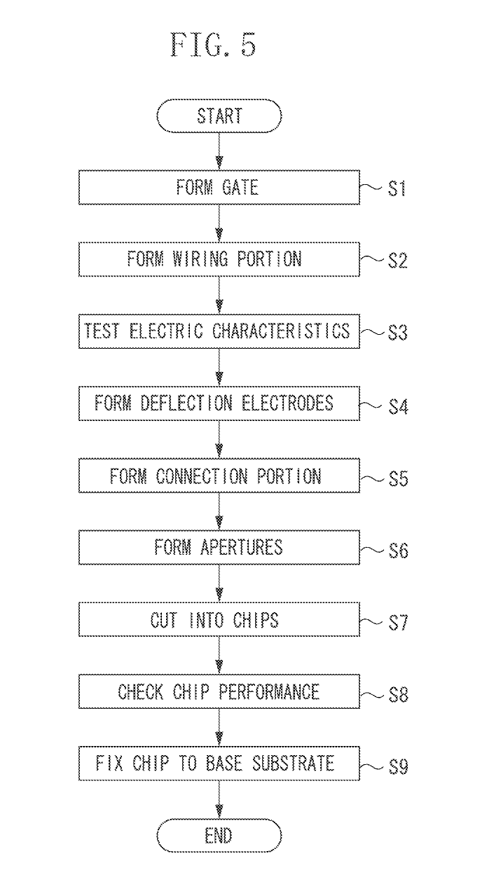

FIG. 5 illustrates the operations of manufacturing the blanking deflector array 117 (device) according to the present exemplary embodiment. The deflector chips 116 are prepared in operations S1 to S8, and are then fixed to the separately prepared base substrate 207 in operation S9.

In operation S1, a gate is formed on a base material (substrate) of chips.

In operation S2, a wiring pattern (wiring portion) is formed on the base material. The wiring pattern is formed by lithography. The wiring pattern may be formed as a wiring layer.

In operation S3, an electric characteristics test is conducted.

In operation S4, the plurality of electrode pairs 201 is formed on the base material by, for example, plating.

In operation S5, the plurality of input terminals is formed on the base material.

In operation S6, the plurality of apertures is formed on the base material by, for example, etching.

In operation S7, the base material is cut by dicing to be divided into a plurality of chips.

The driver 204 and the control circuit 205 are attached to the base material before or after any operation of the above-described steps.

In operation S8, a performance check is conducted for each chip. Defect-free chips are selected by this performance check.

In operation S9, only the chips determined as defect-free chips by the performance check are fixed to the prepared base substrate 207.

According to these steps, if any defect is found during the manufacturing process, this problem may be solved by removing only the chip having the defect, and therefore it is possible to improve the yield rate in the manufacturing. Further, since the possibility that the blanking deflector array has a defect may be reduced, a highly reliable blanking defector array may be manufactured.

The present exemplary embodiment has been described based on the blanking deflector array, but may be applied to a deflector array used for any other purpose than blanking.

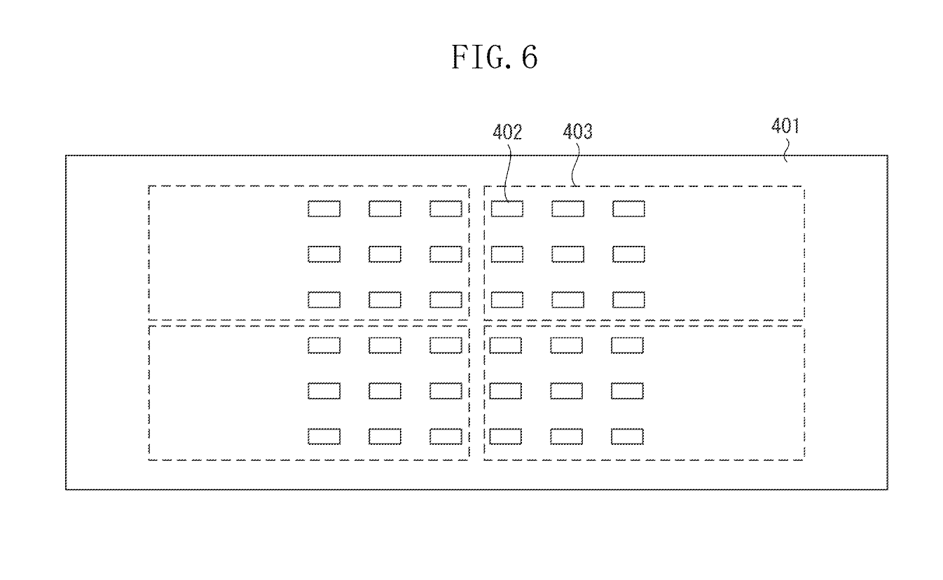

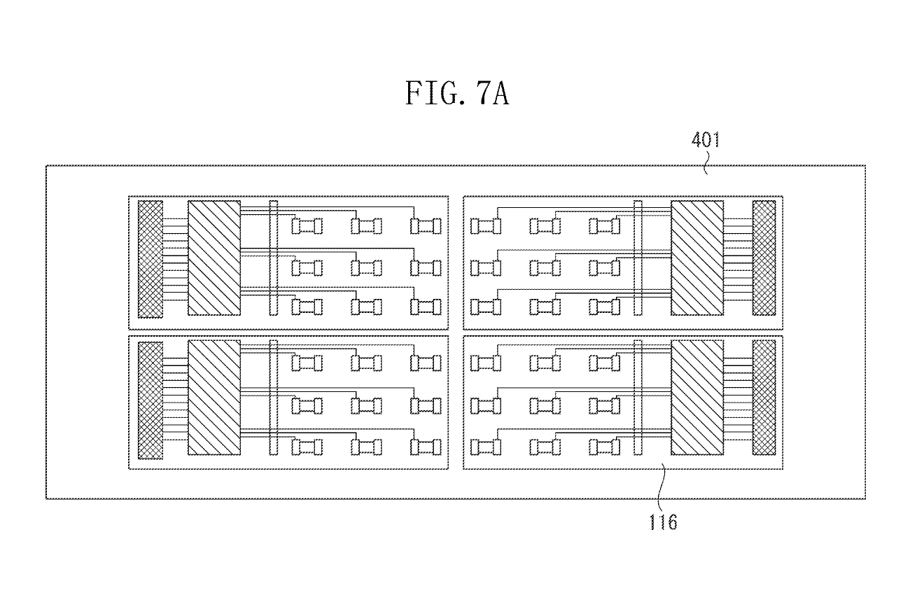

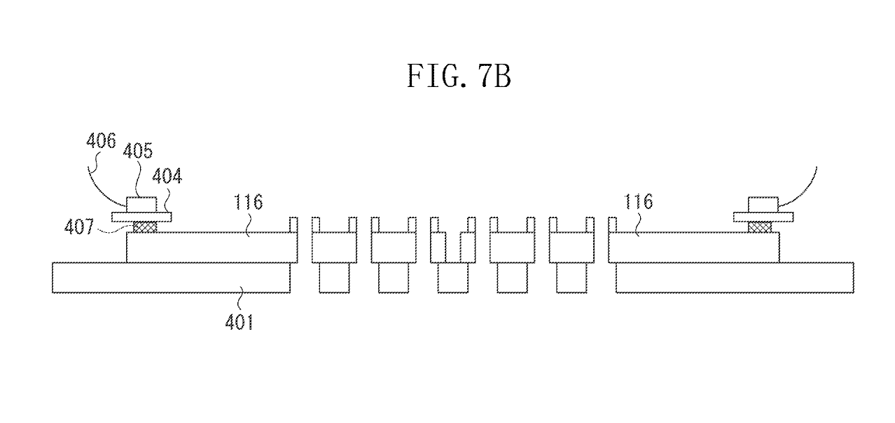

FIGS. 6, 7A, and 7B illustrate a configuration of the blanking deflector array 117 according to a second exemplary embodiment of the present invention. The present exemplary embodiment has different configurations for the base substrate and the wiring connection from those of the first exemplary embodiment. The elements and features of the second exemplary embodiment that will not be specially described below are the same as the corresponding elements and features of the first exemplary embodiment.

FIG. 6 illustrates a base substrate 401 to which the deflector chip 116 is fixed.

The base substrate 401 includes a plurality of apertures 402 formed thereon. The plurality of apertures 402 is formed so as to be located at positions corresponding to a plurality of charged particle beams, and to be arranged in the directions along the top surface of the base substrate 401 (for example, the X and Y directions).

A broken line 403 schematically illustrates where the deflector chip 116 is fixed. A plurality of deflector chips 116 is fixed to one base substrate 401 in parallel with one another in such a manner that the plurality of apertures of the deflector chips 116 are located at positions corresponding to the plurality of apertures of the base substrate 401. In the present exemplary embodiment, the base substrate 401 does not include the terminals 208 and 209 mentioned in the description of the first exemplary embodiment.

FIGS. 7A and 7B illustrate how the deflector chip 116 illustrated in FIG. 2 is fixed to the base substrate 401 illustrated in FIG. 6.

Further, in the first exemplary embodiment, the deflector chip 116 is connected or fixed to the base substrate 207 by the electric connection unit (for example, a bump or a solder). On the other hand, in the present exemplary embodiment, the deflector chip 116 is fixed to the base substrate 401 by, for example, a bonding agent without use of an electric connection unit.

A control signal from the blanking instruction generation circuit 105 is transmitted to a communication processing substrate 404 with a communication processing circuit 405 formed thereon via wiring 406 configured for serial transmission and constituted by an optical fiber or an electric cable.

The present exemplary embodiment employs the serial transmission method, but may employ the parallel transmission method via an optical fiber or an electric cable.

The communication processing substrate 404 and the terminal 206 of the deflector chip 116 are connected to each other via a connection unit 407. In the present exemplary embodiment, this connection is established by the flip chip bonding method, but the connection may be established by a connector connection structure via wiring, or the wire bounding method.

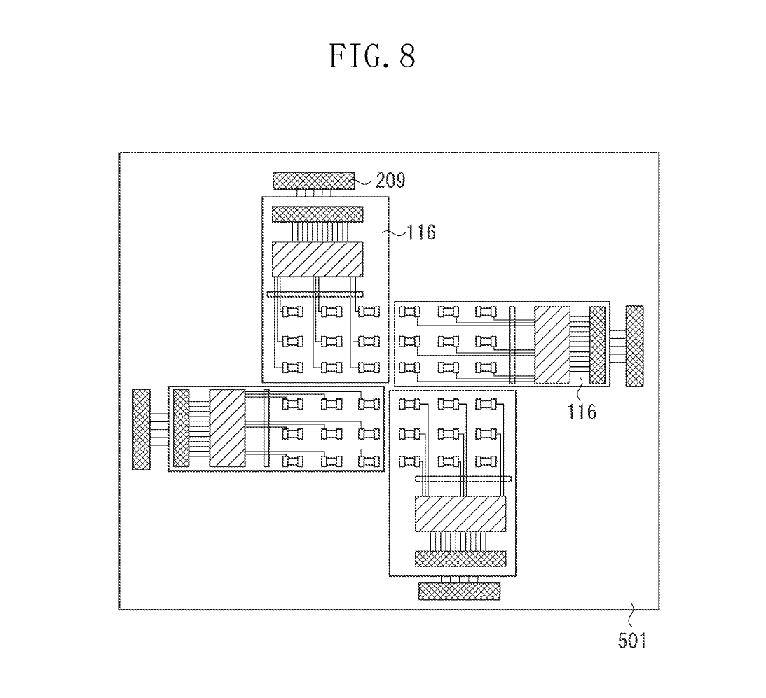

FIG. 8 illustrates a configuration of the blanking deflector array 117 according to a third exemplary embodiment of the present invention. In the third exemplary embodiment, the deflector chips 116 are arranged on a base substrate 501 in a different manner from the arrangements in the above-described exemplary embodiments. The elements and features of the third exemplary embodiment that will not be specially described below are the same as the corresponding elements and features of the first exemplary embodiment.

Four deflector chips 116 are attached to the base substrate 501 in such a manner that they are rotated by 90° relative to one another. According to the present exemplary embodiment, it is possible to pull out wiring in different various directions, the leftward, rightward, upward, and downward directions.

It is possible to increase the degree of freedom about how to connect the blanking deflector array 117 to the blanking instruction generation circuit 105, and reduce the size of the deflector chip 116, thereby improving the yield rate, compared to a blanking deflector array configured as an integrated structure.

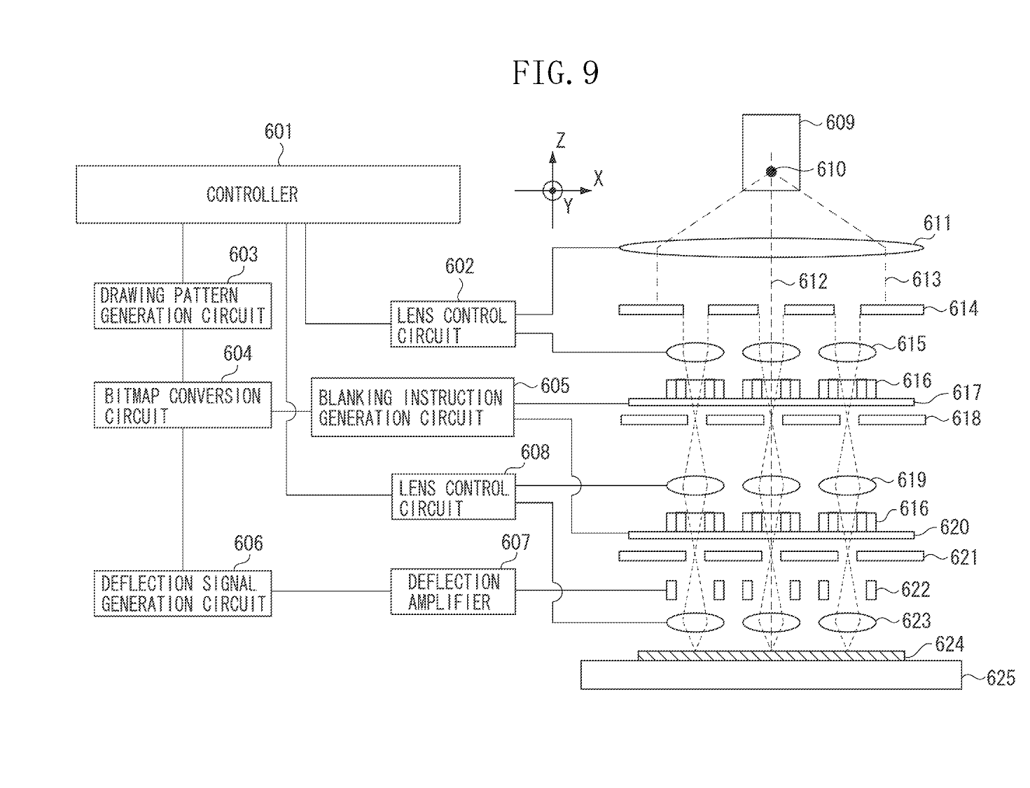

FIG. 9 illustrates a configuration of a multi charged particle beam drawing apparatus according to a fourth exemplary embodiment of the present invention. The elements and features of the fourth exemplary embodiment that will not be specially described below are the same as the corresponding elements and features of the first exemplary embodiment. An electron gun 609 forms a crossover 610. Lines 612 and 613 indicate the path of a charged particle beam spread from the crossover 610.

The charged particle beam spread from the crossover 610 is collimated by a collimator lens 611, which is constituted by an electromagnetic lens, to become a collimated beam, and is incident on an aperture array 614.

The aperture array 614 includes a plurality of circular apertures arranged in a matrix pattern, and the collimated beam incident on the aperture array 114 is divided into a plurality of charged particle beams.

The charged particle beams transmitted through the aperture array 614 are incident on an electrostatic lens 615 constituted by three electrode plates including a plurality of circular apertures (in FIG. 9, vertically aligned three electrode plates are illustrated as an integrated structure).

A blanking aperture 618 having a plurality of apertures arranged in a matrix pattern is disposed at a position where the electrostatic lens 615 forms a first crossover image. The electrostatic lens 615 and the collimator lens 611 are controlled based on a signal from a lens control circuit 602.

Blanking is performed by the blanking aperture 618 and a blanking deflector array 617 including a deflector chip 616 including electrode pairs arranged thereon in a matrix pattern.

The blanking deflector array 617 is controlled based on a blanking signal generated by a drawing pattern generation circuit 603, a bitmap conversion circuit 604, and a blanking instruction generation circuit 605.

The charged particle beams transmitted through the blanking aperture 618 are incident on an electrostatic lens 619. A second blanking aperture 621 including apertures arranged in a matrix pattern is disposed at a position where the electrostatic lens 619 forms a first crossover.

Blanking is performed by the blanking aperture 621 and a blanking deflector array 620 including the deflector chip 616 with electrode pairs arranged thereon in a matrix pattern.

The blanking deflector array 620 is controlled based on a blanking signal generated by the drawing pattern generation circuit 603, the bitmap conversion circuit 604, and the blanking instruction generation circuit 605.

In this way, the charged particle beam drawing apparatus according to the fourth exemplary embodiment performs blanking by the two blanking deflector arrays 617 and 620. More specifically, a part of the plurality of charged particle beams is deflected by one of the blanking deflector arrays 617 and 620, and the remaining charged particle beams are deflected by the other of the blanking deflector arrays 617 and 620. This configuration may reduce the limitation on the space for wiring, even if the charged particle beam drawing apparatus uses a large number of charged particle beams in total.

The charged particle beams transmitted through the blanking aperture 621 are focused by an electrostatic lens 623, and form the image of the crossover 610 on a substrate 624 such as a wafer or a mask.

During pattern drawing, the substrate 624 is continuously shifted in the Y direction by a stage 625. The image formed on the surface of the substrate 624 is deflected in the X direction by a deflector 622, and is blanked by the blanking deflector arrays 617 and 620, based on a result of real-time length measurement by a laser length measurement unit. The deflector 622 is controlled based on a signal from a deflection signal generation circuit 606 via a deflection amplifier 607. The electrostatic lens 623 is controlled based on a signal from a lens control circuit 608. A controller 601 provides overall control of these control circuits. However, the control system is not limited to the above-described system.

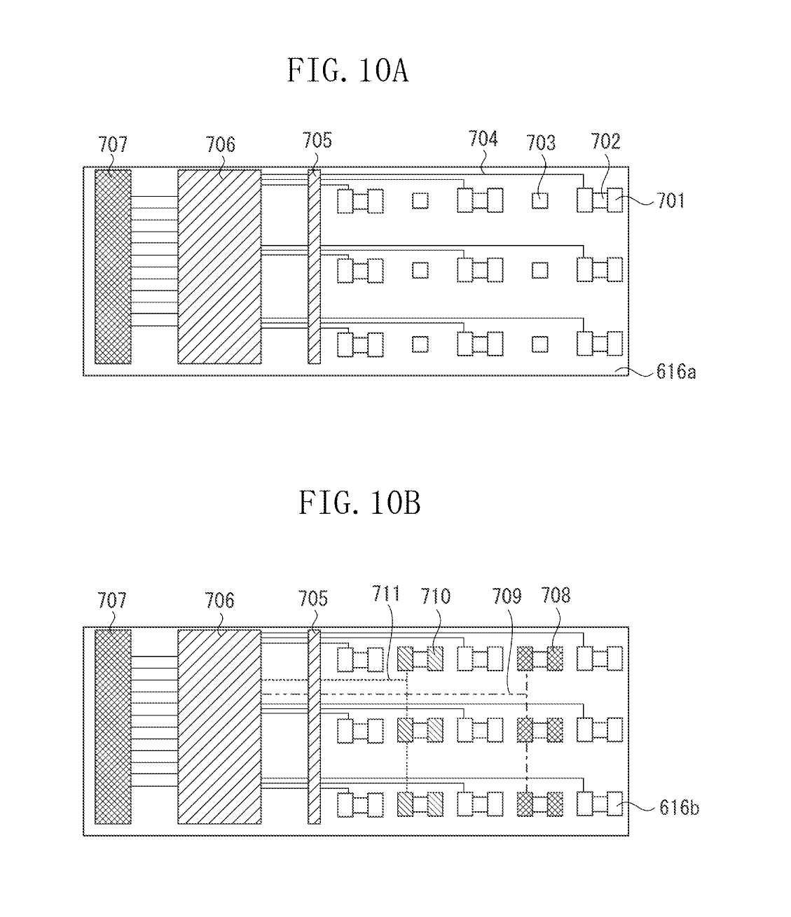

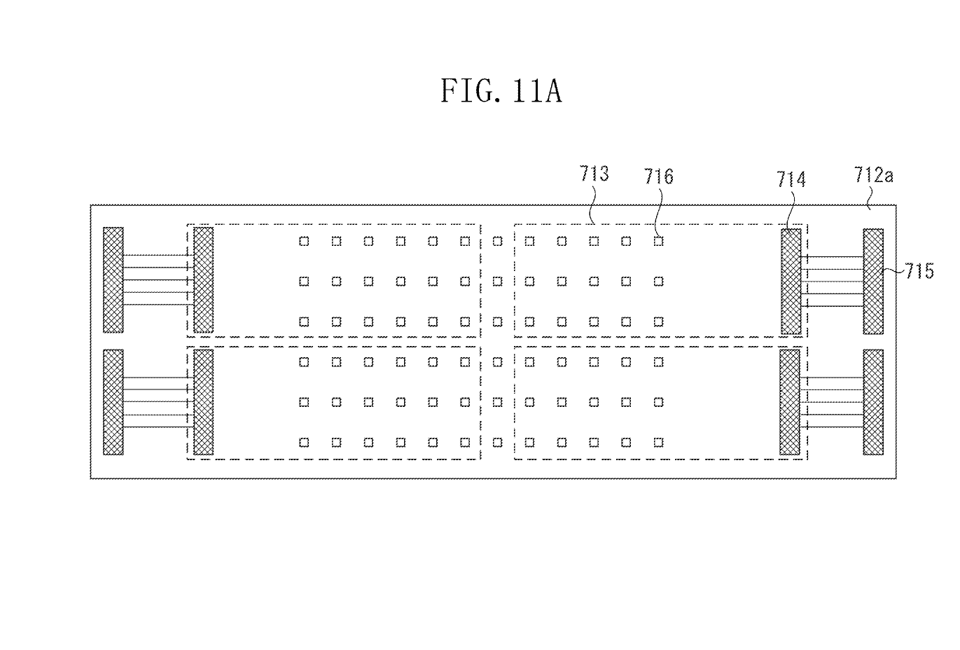

FIGS. 10A to 12B illustrate the configurations of the blanking deflector arrays 617 and 620.

FIG. 10A illustrates the deflector chip 616a. The deflector chip 616a includes a plurality of apertures 702 and 703 through which charged particle beams may be transmitted, a plurality of electrode pairs 701 disposed on the both sides of the apertures 702, and a driver (switching element) 705 configured to apply voltage for driving the electrode pairs 701. In the present exemplary embodiment, the plurality of electrode pairs 701 is disposed on a part of the plurality of apertures, unlike the first exemplary embodiment. In the present exemplary embodiment, the plurality of electrode pairs 701 is disposed on every other column among the plurality of apertures arranged in a square matrix pattern.

Further, the deflector chip 616a includes a control circuit 706 for controlling the driver 705, and a wiring pattern 704 for connecting the control circuit 706 and the respective electrode pairs 701. Further, the deflector chip 616a includes a terminal 707 constituted by, for example, a bump or a pad mainly made of a solder, Cu, or Au material for inputting an ON/OFF signal of each charged particle beam from the blanking instruction generation circuit 605.

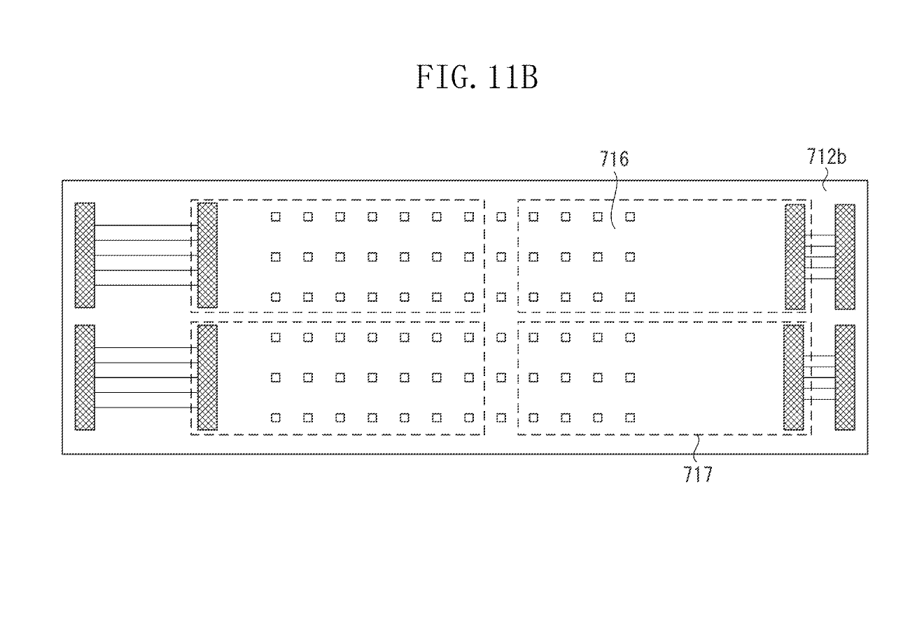

FIG. 11A illustrates a base substrate 712a (first base substrate) to which the deflector chip 616a is fixed. FIG. 11B illustrates a base substrate 712b (second base substrate) to which the deflector chip 616a is fixed. In the following, FIGS. 11A and 11B will be described using a same reference numeral for a unit that functions in a similar manner.

The base substrates 712a and 712b each include a plurality of apertures 716 formed thereon. Further, the base substrates 712a and 712b each include terminals 714 and 715 for relaying an ON/OFF signal of each charged particle beam from the blanking instruction generation circuit 605 to the deflector chip 616a. The terminals 714 and 715 each are constituted by, for example, a bump or a pad mainly made of a solder, Cu, or Au material. The plurality of apertures 716 are formed so as to be located at positions corresponding to the plurality of charged particle beams (i.e., positions corresponding to the apertures of the aperture array), and to be arranged in the directions along the top surface of the base substrate 712a or 712b (for example, the X and Y directions).

Further, the base substrates 712a and 712b each include a wiring pattern for connecting the terminals 714 and 715. The broken line 713 schematically indicates where the deflector chip 616a is fixed on the blanking deflector array 617. Similarly, the broken line 713 schematically indicates where the deflector array 616a is fixed on the blanking deflector array 620.

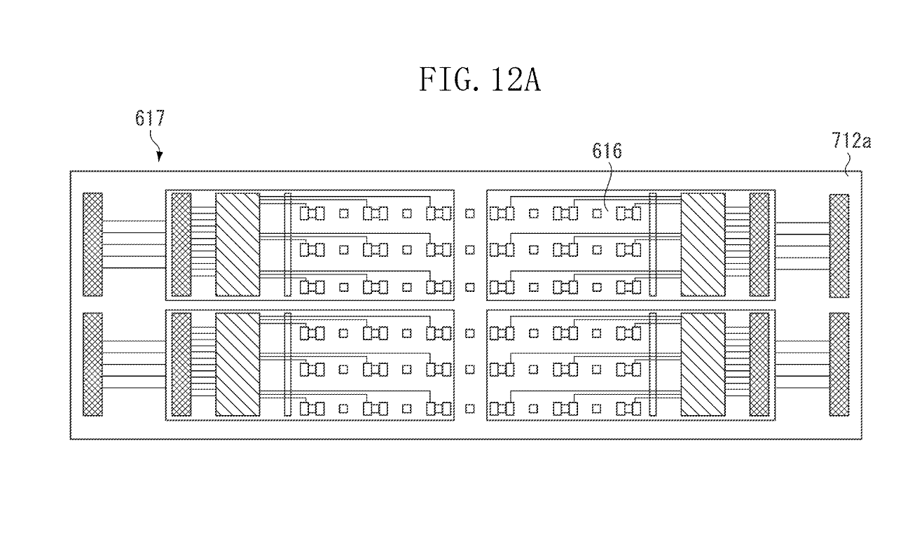

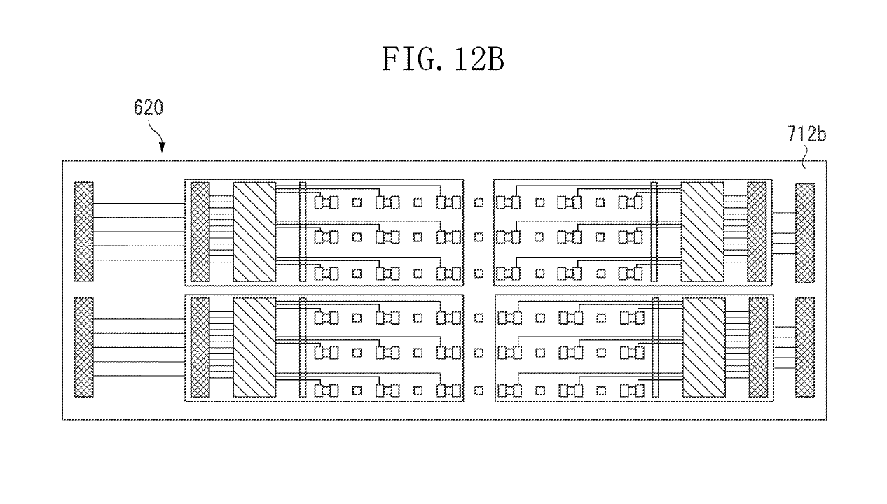

FIG. 12A illustrates how the deflector chip 616a is fixed on the base substrate 712a, and FIG. 12B illustrates how the deflector chip 616a is fixed on the base substrate 712b.

In the present exemplary embodiment, the electrode pairs of the deflector chip 616a are disposed on every other column, and the deflector chips 616a fixed to the base substrate 712b are arranged offset by one column from the arrangement of the deflector chips 616a fixed to the base substrate 712a. In other words, the plurality of deflector chips 616a is fixed to the base substrates 712a and 712b so that the plurality of deflector chips 616a fixed to the base substrate 712b is arranged out of alignment by at least one aperture relative to the arrangement of the plurality of deflector chips 616a fixed to the base substrate 712a. Therefore, it is possible to use the same kind of deflector chip 616a for the two base substrates 712a and 712b. In the present exemplary embodiment, the plurality of electrode pairs is disposed on every other column among the plurality of apertures arranged in a square matrix pattern. However, the arrangement of the electrode pairs is not limited thereto. For example, the electrode pairs may be arranged on every couple of columns. Further, a deflector chip having a staggered arrangement may be fixed to the base substrate 712a and the base substrate 712b.

The electrode pair is not disposed on a part of the plurality of apertures on the deflector chip 616a. Further, the deflector chips 616a are positioned in such a manner that the apertures without the electrode pair provided thereto, among the apertures on the plurality of deflector chips 616a fixed to any one of the base substrates 712a and 712b, correspond to the apertures with the electrode pair provided thereto, among the apertures of the plurality of deflector chips 616a fixed to the other of the base substrates 712a and 712b. The plurality of deflector chips 616a is fixed to the base substrates 712a and 712b so that the plurality of deflector chips 616a fixed to the base substrate 712a and the plurality of deflector chips 616a fixed to the base substrate 712b are out of alignment with each other.

As a result, it is possible to improve the yield rate in manufacturing of the blanking deflector arrays 617 and 620. Further, the present exemplary embodiment is advantageous in terms of cost.

The present exemplary embodiment employs base substrates having differently positioned terminals as the base substrates 712a and 712b. However, the present exemplary embodiment may be also carried out by using identical base substrates, and in this case, arranging them out of alignment with each other.

FIG. 10B illustrates a variation of the fourth exemplary embodiment. This variation is an example replacing at least a part of the deflector chips 616a of the blanking deflector arrays 617 and 620 with a deflector chip illustrated in FIG. 10B. As one nonlimiting example, in this variation, the deflector chips 616a are fixed to the blanking deflector array 712a, and the deflector chips 616b are fixed to the blanking deflector array 712b.

The deflector chip 616b includes a plurality of apertures formed thereon, through which charged particle beams may be transmitted, a plurality of electrode pairs 701, 708, and 710 disposed on the both sides of the apertures, and the driver (switching element) 705 configured to apply voltage for driving the electrode pairs. The present variation mainly uses the electrode pairs 701 disposed on every other column in a similar manner as the deflector chip 616a illustrated in FIG. 10A, and uses the electrode pairs 708 and 710 only when a defect occurs at the electrode pairs 701. In other words, providing electrode pairs redundantly allows the charged particle beam drawing apparatus to continue working even when a defect occurs at the electrode pairs 701. In this case, this situation may be solved by replacing the defective blanking defector array or the defective deflector chip at the time of regular maintenance. This fault tolerance is greatly contributive to improvement of the throughput as a production apparatus.

Next, a method for manufacturing a device (for example, a semiconductor device and a liquid crystal display device) according to an exemplary embodiment of the present invention will be described. A semiconductor device is manufactured by performing the front-end processing and the back-end processing. The front-end processing forms an integrated circuit on a wafer. The back-end processing completes the integrated circuit chip on the wafer prepared by the front-end processing as a product. The front-end processing includes the process of drawing a pattern on a wafer coated with a photosensitive material with use of the above-described charged particle beam drawing apparatus, and the process of developing the wafer. The back-end processing includes the assembly process (dicing and bonding), and the packaging process (encapsulation). A liquid crystal display device is manufactured by performing the processing of forming a transparent electrode. The processing of forming a transparent electrode includes the process of applying a photosensitive material onto a glass substrate with a transparent conductive film deposited thereon, the process of drawing a pattern on the glass substrate coated with the photosensitive material with use of the above-described charged particle beam drawing apparatus, and the process of developing the glass substrate. According to the device manufacturing method of the present exemplary embodiment, it is possible to manufacture a higher quality device, compared to one manufactured by conventional methods.

According to the exemplary embodiments of the present invention, it is possible to provide a highly reliable deflector array.

While the present invention has been described with reference to exemplary embodiments, it is to be understood that the invention is not limited to the disclosed exemplary embodiments. The scope of the following claims is to be accorded the broadest interpretation so as to encompass all modifications, equivalent structures, and functions.

This application claims priority from Japanese Patent Application No. 2010-251162 filed Nov. 9, 2010, which is hereby incorporated by reference herein in its entirety.

What is claimed is:

1. A deflector array comprising:
a first base substrate including a plurality of apertures formed thereon; and
a plurality of deflector chips including a plurality of apertures formed thereon, and a plurality of electrode pairs disposed at both sides of at least a part of the plurality of apertures,
wherein the plurality of deflector chips is fixed to the first base substrate in such a manner that the plurality of apertures of the deflector chips is arranged at positions corresponding to the plurality of apertures of the first base substrate.

2. The deflector array according to claim 1, wherein the plurality of deflector chips includes a wiring portion for applying voltage to the electrode pairs.

3. The deflector array according to claim 2, wherein the plurality of deflector chips includes a driver for applying voltage to the electrode pairs.

4. The deflector array according to claim 1, wherein the plurality of deflector chips fixed to the first base substrate has identical shapes.

5. The deflector array according to claim 1, wherein at least two of the plurality of deflector chips are fixed to the base substrate at different mounting angles from each other.

6. The deflector array according to claim 1, further comprising a second base substrate including a plurality of apertures formed thereon, the plurality of apertures being arranged at positions corresponding to the plurality of apertures of the first base substrate,
wherein the plurality of deflector chips is fixed to the second base substrate in parallel with one another in such a manner that the plurality of apertures of the deflector chips is arranged at positions corresponding to the plurality of apertures of the second base substrate.

7. The deflector array according to claim 6, wherein the plurality of deflector chips fixed to the first base substrate and the plurality of deflector chips fixed to the second base substrate have identical shapes, and no electrode pair is disposed at apart of the plurality of apertures of the deflector chips, and
wherein the plurality of deflector chips fixed to the first base substrate and the plurality of deflector chips fixed to the second base substrate are fixed out of alignment with each other, so that the apertures without the electrode pair provided thereto, among the apertures of the plurality of deflector chips fixed to one of the first base substrate and the second base substrate, correspond to the apertures with the electrode pair provided thereto, among the apertures of the plurality of deflector chips fixed to the other of the base substrate and the second base substrate.

8. A charged particle beam drawing apparatus configured to draw a pattern on a substrate using a plurality of charged particle beams, the charged particle beam drawing apparatus comprising:
an aperture array configured to form a plurality of charged particle beams; and
a blanking deflector array configured to perform blanking by deflecting the plurality of charged particle beams,
wherein the blanking deflector array includes:
a base substrate including a plurality of apertures formed thereon, through which the plurality of charged particle beams is transmittable; and
a plurality of deflector chips including a plurality of apertures formed thereon, and a plurality of electrode pairs disposed at both sides of at least a part of the plurality of apertures, and
wherein the plurality of deflector chips is fixed to the base substrate in such a manner that the plurality of apertures of the deflector chips is arranged at positions corresponding to the plurality of apertures of the base substrate.

9. A device manufacturing method comprising:
drawing a pattern on a substrate using the charged particle beam drawing apparatus according to claim 8; and
developing the substrate.

10. A method for manufacturing a deflector array, the method comprising:
forming a plurality of apertures and a plurality of electrode pairs on a substrate;
dividing the substrate into a plurality of chips;
preparing a base substrate including a plurality of apertures; and
fixing the plurality of chips to the base substrate in such a manner that the plurality of apertures of the deflector chips is arranged at positions corresponding to the plurality of apertures of the base substrate.
